(19) United States
(12) Patent Application Publication
(10) Pub. No.: US 2021/0391154 A1
(43) Pub. Date: Dec. 16, 2021

(54) ANISOTROPIC ETCH APPARATUS WITH LOCAL ETCH DIRECTION ADJUSTMENT CAPABILITY AND METHODS FOR OPERATING THE SAME

(71) Applicant: SANDISK TECHNOLOGIES LLC, Addison, TX (US)

(72) Inventors: Syo FUKATA, Yokkaichi (JP); Shoichi MURAKAMI, Yokkaichi (JP); Shigeru NAKATSUKA, Yokkaichi (JP); Yusuke OSAWA, Yokkaichi (JP); Shigehiro FUJINO, Yokkaichi (JP); Masaaki HIGASHITANI, Cupertino, CA (US)

(21) Appl. No.: 16/900,126

(22) Filed: Jun. 12, 2020

(51) Int. Cl. H01J 37/32; H01L 21/687

(52) U.S. Cl. CPC H01J 37/32733; H01L 21/68785; H01J 2237/3321; H01J 37/32091; H01J 37/3244; H01J 37/32715

(57) ABSTRACT

An anisotropic etch apparatus contains an electrostatic chuck located in a vacuum enclosure and including a lower electrode, an upper electrode overlying the lower electrode and located in the vacuum enclosure, a main radio frequency (RF) power source configured to provide an RF bias voltage between the lower electrode and the upper electrode, and a plurality of conductive edge ring segments surrounding the electrostatic chuck and configured for at least one of independent vertical movement relative to the electrostatic chuck or for independently receiving a different RF bias voltage.

### FIELD

The present disclosure relates generally to the field of semiconductor manufacturing apparatuses and particularly to an anisotropic etch apparatus with local etch direction adjustment capability and methods for operating the same.

### BACKGROUND

During a reactive ion etch process, ions accelerated along the direction of local electric field and impinges on an etch target, such as a semiconductor substrate with a patterned etch mask layer thereupon. In order to form etch patterns extending perpendicular to the top surface of the substrate, the electric field lines need to be perpendicular to the top surface of the semiconductor substrate. This is mostly the case in the middle portion of the semiconductor substrate. However, the contour of electric field lines overlying edge portions of the semiconductor substrate is affected by the local geometry of conductive components of the reactive ion etch apparatus, such as the edge ring. Thus, etch direction on edge dies on the semiconductor substrate can have significant tilt from the vertical direction, and can adversely impact the yield of semiconductor dies on the semiconductor substrate.

### SUMMARY

According to an aspect of the present disclosure, an anisotropic etch apparatus contains an electrostatic chuck located in a vacuum enclosure and including a lower electrode therein, a plurality of conductive outer edge ring segments surrounding the electrostatic chuck and configured for independent vertical movement relative to the electrostatic chuck, an upper electrode overlying the lower electrode and located in the vacuum enclosure, and a main radio frequency (RF) power source configured to provide radio frequency bias voltage between the lower electrode and the upper electrode.

According to another embodiment an anisotropic etch apparatus contains an electrostatic chuck located in a vacuum enclosure and including a lower electrode therein, an upper electrode overlying the lower electrode and located in the vacuum enclosure, a main radio frequency (RF) power source configured to provide radio frequency bias voltage between the lower electrode and the upper electrode, a plurality of electrically isolated, conductive edge ring segments surrounding the electrostatic chuck, and a plurality of auxiliary RF power sources, each of which is configured to independently provide a different auxiliary RF bias voltage to one of the conductive edge ring segments.

### BRIEF DESCRIPTION OF THE DRAWINGS

FIG. 1A is a vertical cross-sectional view of an exemplary anisotropic etch apparatus according to a first embodiment of the present disclosure. FIG. 1B is a top-down view of an edge ring of the exemplary anisotropic etch apparatus of FIG. 1A.

FIG. 1C is a vertical cross-sectional view of an exemplary anisotropic etch apparatus according to a second embodiment of the present disclosure. FIG. 1D is a top-down view of an edge ring of the exemplary anisotropic etch apparatus of FIG. 1C. The plane C-C′ in FIG. 1D corresponds to the view of FIG. 1C.

FIG. 1E is a schematic perspective view of an edge ring of a third embodiment of the present disclosure.

FIG. 2A is a vertical cross-sectional view of a portion of the exemplary anisotropic etch apparatus of FIGS. 1A and 1B while a conductive outer edge ring segment is in a raised configuration.

FIG. 2B is a vertical cross-sectional view of a portion of the exemplary anisotropic etch apparatus of FIGS. 1A and 1B while a conductive outer edge ring segment is in a middle configuration.

FIG. 2C is a vertical cross-sectional view of a portion of the exemplary anisotropic etch apparatus of FIGS. 1A and 1B while a conductive outer edge ring segment is in a retracted configuration.

### DETAILED DESCRIPTION

As discussed above, the present disclosure is directed to an anisotropic etch apparatus with local etch direction adjustment capability and methods for operating the same, the various aspects of which are described herebelow in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

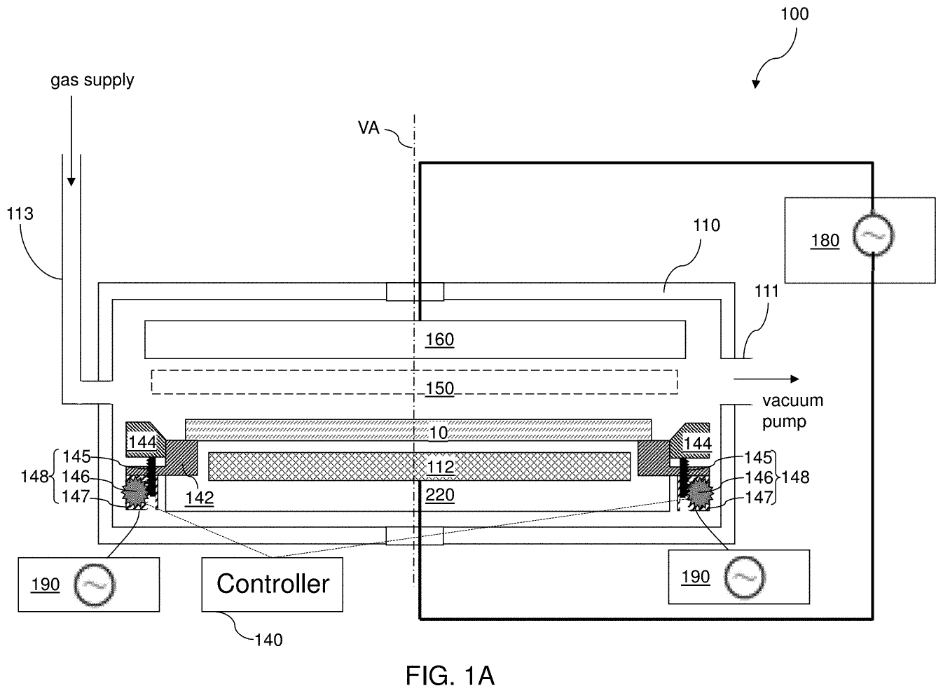

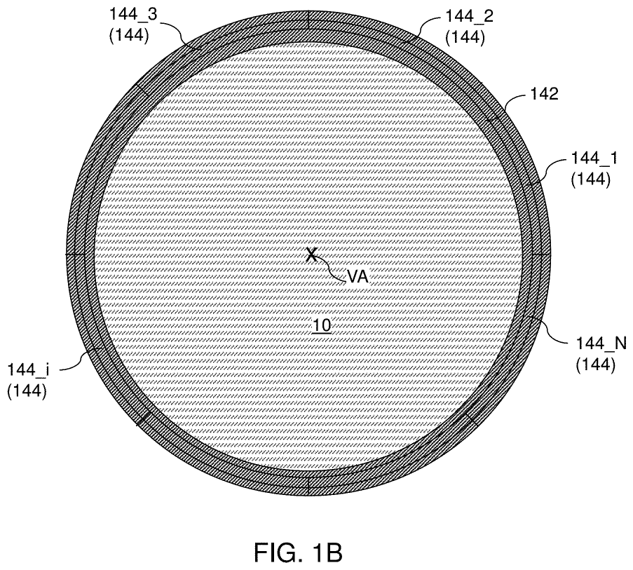

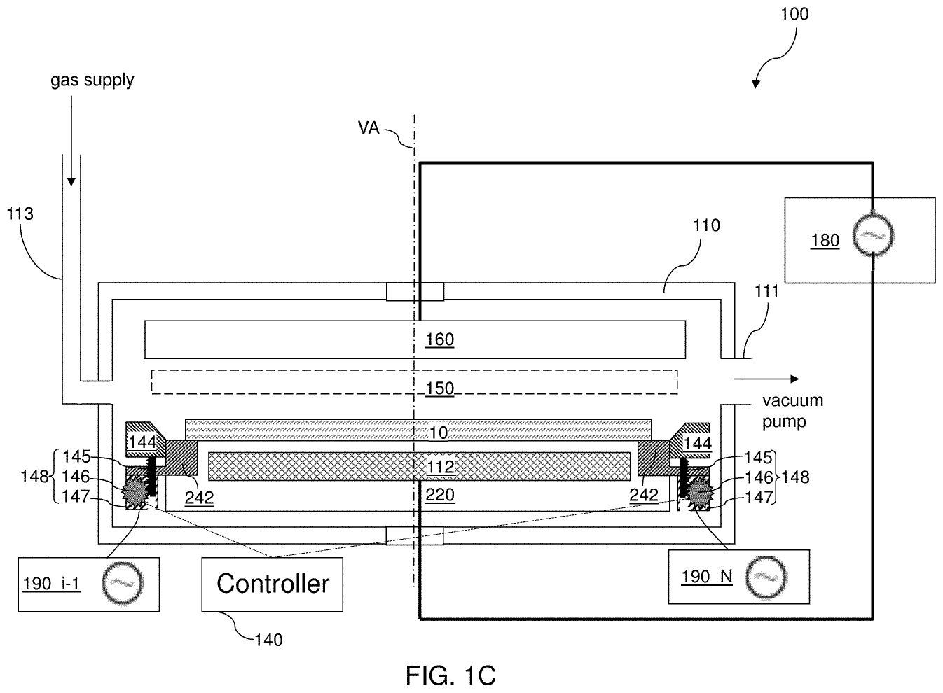

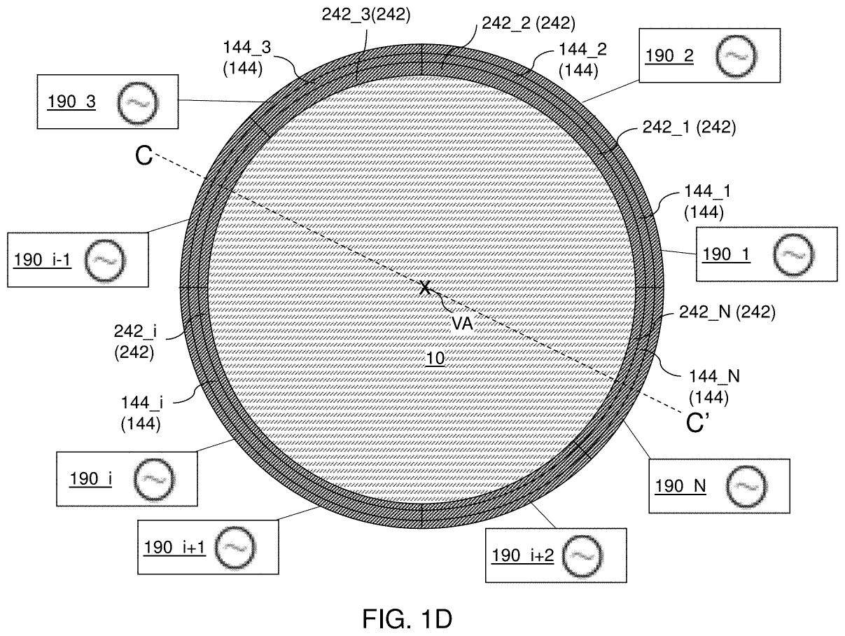

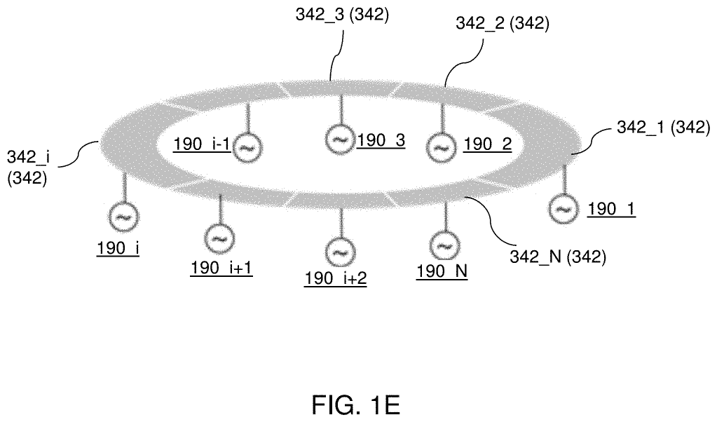

Referring to FIGS. 1A and 1B, an exemplary anisotropic etch apparatus 100 according to an embodiment of the present disclosure is illustrated. The exemplary anisotropic etch apparatus 100 includes a process chamber configured to perform an anisotropic etch process, such as a reactive ion etch process. The exemplary anisotropic etch apparatus 100 includes a vacuum chamber defined by a vacuum enclosure 110. The vacuum enclosure 110 includes multiple components such as static enclosure walls and at least one sealable opening that can be sealed by a movable door or a movable cap. For example, an opening may be provided in a sidewall of the static enclosure walls, and a slit valve may be provided to enable transfer of a substrate (such as a semiconductor wafer) therethrough. The slit valve may be configured to move out of the path of the transfer of the substrate during the transfer of the substrate, and slide into a sealing position once the substrate transfer is complete. The opening in the static enclosure walls may be connected to a transfer chamber (not illustrated), which may be maintained under vacuum or under reduced pressure to minimize influx of contaminants into the vacuum chamber and to facilitate maintenance of the base pressure within the vacuum enclosure 110. At least one vacuum pump (not expressly shown) can be attached to the vacuum enclosure 110 through a pumping port 111. The at least one vacuum pump can be configured to maintain the base pressure of the vacuum enclosure 110 in a range from 0.01 mTorr to 1 mTorr after a suitable outgas sing process. The at least one vacuum pump may include a tandem combination of a turbo pump and a mechanical pump. The mechanical pump may be connected to the exhaust of the turbo pump, and can function as a roughing pump. The intake side of the turbo pump can be connected to the pumping port of the vacuum enclosure 110 to enable low base pressure in the vacuum enclosure 110.

A gas supply manifold 113 configured to provide influx of at least one process gas into the vacuum enclosure 110 may be provided in the exemplary anisotropic etch apparatus 100. The at least one process gas may include any process gas that can be employed for any known anisotropic etch process in the art. For example, the at least one process gas can include at least one gas phase etchant (e.g., a fluorine and/or a chlorine containing gas), and may also include an oxidant, a reducing agent, and/or a carrier gas (e.g., hydrogen or argon). The gas supply manifold 113 may be configured to provide influx of the at least one process gas through a sidewall of the vacuum enclosure 110 located on an opposite side of the pumping port 111. Optionally, the gas supply manifold may be configured to provide a purge gas and/or a backfill gas.

An electrostatic chuck 220 is located within the vacuum enclosure 110. The electrostatic chuck 220 includes a dielectric matrix having a planar top surface on which a substrate 10 (such as a semiconductor wafer) can be disposed. The electrostatic chuck 220 includes a lower electrode 112. The lower electrode 112 can have a uniform thickness, and can include a conductive material, such as a metallic material. The lower electrode 112 may be encased within a dielectric matrix material of the electrostatic chuck 220, which may include a ceramic material, quartz, aluminum oxide, or any other suitable dielectric material that can provide mechanical strength and can withstand the elevated temperature during a deposition process.

In one embodiment, the electrostatic chuck 220 has a circular horizontal cross-sectional shape, the lower electrode 112 can have a circular horizontal cross-sectional shape with a smaller diameter than the circular horizontal cross-sectional shape of the electrostatic chuck 220. In one embodiment, electrostatic chuck 220 may have an axial symmetry around a vertical axis VA passing through the geometrical center of the electrostatic chuck 220.

An upper electrode 160 is located over the electrostatic chuck 220. The lower electrode 112 and the upper electrode 160 can be connected to output nodes of at least one primary radio frequency (RF) power source 180. The at least one primary RF power source 180 can be configured to provide a radio frequency bias voltage between the lower electrode 112 and the upper electrode 160. The lower electrode 112 and the upper electrode 160 may be powered by a common RF power source 180, or may be powered by two separate primary RF power sources that can independently control the power transmitted through the lower electrode 112 and the upper electrode 160.

According to an aspect of the present disclosure, a plurality of conductive outer edge ring segments 144 are provided, which are configured for independent vertical movement relative to the electrostatic chuck 220. The plurality of conductive outer edge ring segments 144 collectively function as a component of an edge ring that contacts a substrate 10 that is disposed on the electrostatic chuck 220. The plurality of conductive outer edge ring segments 144 laterally surround the electrostatic chuck 220.

In one embodiment, an annular conductive edge ring 142 may be provided around an upper periphery of the electrostatic chuck 220. The annular conductive edge ring 142 can laterally surround the electrostatic chuck 220, and may be concentric with the electrostatic chuck 220. The annular conductive edge ring 142 may have a top surface that is flush with the top surface of the electrostatic chuck 220. A cylindrical inner sidewall of the annular conductive edge ring 142 can contact a sidewall of the electrostatic chuck 220. The annular conductive edge ring 142 can be affixed to the electrostatic chuck 220 by tight fit and/or by at least one fixture element such as a screw, clamp and/or a pin. In one embodiment, the annular conductive edge ring 142 can be configured to contact a bottom surface of a substrate 10 that is disposed on top of the electrostatic chuck 220.

The plurality of conductive outer edge ring segments 144 can be electrically connected to the annular conductive edge ring 142. For example, the plurality of conductive outer edge ring segments 144 can contact a respective portion of a cylindrical outer sidewall of the annular conductive edge ring 142. In this case, each of the plurality of conductive outer edge ring segments 144 can be electrically connected to the substrate 10 through the annular conductive edge ring 142. In one embodiment, each of the plurality of conductive outer edge ring segments 144 can comprise a respective inner sidewall that contacts a respective portion of a cylindrical outer sidewall of the annular conductive edge ring 142.

In one embodiment, each inner sidewall of the plurality of conductive outer edge ring segments 144 can be vertical, and can have a concave profile in a horizontal cross-sectional view. Such an inner sidewall is herein referred to as a concave vertical sidewall. The cylindrical outer sidewall of the annular conductive edge ring 142 can be a convex vertical sidewall, i.e., a sidewall having a vertical profile (i.e., without any tilt angle with respect to the vertical direction) in a vertical cross-sectional view and having a convex profile in a horizontal cross-sectional view.

The plurality of conductive outer edge ring segments 144 can have the same size, and can laterally extend by a same azimuthal angle around the vertical axis VA passing through the geometrical center of the electrostatic chuck 220. The total number of conductive outer edge ring segments 144 can be N, which is an integer greater than 2, i.e., an integer such as 3, 4, 5, 6, 7, 8, etc. In this case, each of the conductive outer edge ring segments 144 can azimuthally extend around the vertical axis VA passing through the geometrical center of the electrostatic chuck 220 by an azimuthal angle range of 2π/N.

In one embodiment, the plurality of conductive outer edge ring segments 144 comprises N conductive outer edge ring segments 144, in which N is in a range from 3 to 60. Each of the conductive outer edge ring segments 144 can be numerically numbered employing integers beginning with 1. Thus, if N conductive outer edge ring segments 144 are provided, the N conductive outer edge ring segments 144 can include a first conductive outer edge ring segment 144_1, a second conductive outer edge ring segment 144_2, a third conductive outer edge ring segment 144_3, and so on up to the N-th conductive outer edge ring segment 144_N. An i-th conductive outer edge ring segment 144_i can be located between an (i−1)-th conductive outer edge ring segment 144_(i−1) and an (i+1)-th conductive outer edge ring segment 144_(i+1) for all i other than 1 and N. In one embodiment, each of the plurality of conductive outer edge ring segments 144 can have an azimuthal extent in a range from π/30 radian to 2π/3 radian. In one embodiment, the N conductive outer edge ring segments 144 can be arranged with an N-fold rotational symmetry around the vertical axis VA passing through the geometrical center of the electrostatic chuck 220 in a plan view, i.e., a view along a downward vertical direction.

In one embodiment, each of the plurality of conductive outer edge ring segments 144 can comprise a tapered top surface having a height that increases with a radial distance from the vertical axis VA passing through the geometrical center of the electrostatic chuck 220. The tapered top surface of the conductive outer edge ring segments 144 has the effect of gradually changing the equipotential line, which extends across all surfaces of the plurality of conductive outer edge ring segments 144, all surfaces of the annular conductive edge ring 142, and the surfaces of the substrate 10 (unless charge accumulation occurs within the substrate 10 during an anisotropic etch process). According to an aspect of the present disclosure, the height of the conductive outer edge ring segments 144 can be independently adjusted before, during, and/or after an anisotropic etch process to change the contour of the equipotential line. Changing the contour of the equipotential line around the periphery of a substrate 10 has the effect of tilting the impingement direction of charged ions during the anisotropic etch process, and thus, causes a change in the tilt angle of trenches or openings formed within films (e.g., insulating, semiconductor and/or conductive layers) located over the top surface of the substrate 10.

According to an embodiment of the present disclosure, a plurality of height adjustment assemblies 148 can be provided. For example, a separate height adjustment assembly 148 can be provided for each conductive outer edge ring segment 144. Each height adjustment assembly 148 can be configured to independently elevate or lower a respective one of the plurality of conductive outer edge ring segments 144. Generally, each of the plurality height adjustment assemblies 148 comprises an actuator 147 located within the vacuum enclosure 110 or outside the vacuum enclosure 110 and configured to actuate vertical movement of a respective height adjustment assembly 148.

Further, each of the plurality height adjustment assemblies 148 comprises moving parts (145, 146) that are actuated and move in a linear motion or in a rotational motion. Any combination of moving parts (145, 146) that can vertically move the ring segments 144 may be employed for the height adjustment assemblies 148. Examples of moving parts (145, 146) that may be employed for the respective height adjustment assemblies 148 include, but are not limited to, racks and pinions, worm gears (e.g., worm drive), bevel gears, and/or any other mechanical part that may produce a vertical linear motion.

The actuators 147 may be motorized, or may be configured to be manually adjusted. In case the actuators 147 are motorized, a differential height controller 140 may be provided to enable individual adjustment of the height of the conductive outer edge ring segments 144 without opening the vacuum enclosure 110. The differential height controller 140 can be configured to independently actuate each of the actuators 147 for the plurality of height adjustment assemblies 148 via a wired or wireless data connection. In case the actuators 147 are not motorized, each of the plurality height adjustment assemblies 148 can be configured to mechanically actuate a respective one of the plurality of conductive outer edge ring segments 144 upon application of physical force thereto.

In one embodiment, the annular conductive edge ring 142 comprises a laterally-protruding flange portion including holes, and each height adjustment assembly 148 comprises a component (e.g., worm gear or rack gear) that vertically extends through a respective hole in the laterally-protruding flange portion of the annular conductive edge ring 142. In one embodiment, each of the plurality of conductive outer edge ring segments 144 may be configured to vertically move by at least 1 mm, such as from 1 mm to 10 mm.

A volume between the electrostatic chuck 220 and the upper electrode 160 comprises a plasma zone 150. The plurality of conductive outer edge ring segments 144 can be arranged along a periphery of the plasma zone 150 to affect the equipotential line around the periphery of the plasma zone 150 during the anisotropic etch process. Thus, independent adjustment of the height of the conductive outer edge ring segments 144 around the electrostatic chuck 220 can result in azimuthally independent adjustment of etch direction along the periphery of the substrate 10.

In one embodiment, the electrostatic chuck 220 and the upper electrode 160 are vertically spaced from each other by a uniform spacing, and at least two of the plurality of conductive outer edge ring segments 144 can be vertically spaced from the upper electrode 160 by different vertical spacings from each other.

In one embodiment the edge ring 142 and the conductive outer edge ring segments 144 may be electrically connected to at least one optional auxiliary RF power source 190 in addition to the at least one primary RF power source 180. In the first embodiment shown in FIG. 1B, the edge ring 142 comprises a unitary ring. In this embodiment, a single auxiliary RF power source 190 may be electrically connected to the edge ring 142 and configured to apply the same RF bias voltage to the edge ring 142 and to all conductive outer edge ring segments.

In second embodiment shown in FIGS. 1C and 1D, the inner edge ring 242 may also be divided into separate conductive inner edge ring segments 242_1 to 242_N which are electrically isolated from each other. There may be the same number of inner edge ring segments 242 as there are outer edge ring segments 144_i. The plurality of inner edge ring segments 242 can have the same size, and can laterally extend by a same azimuthal angle around the vertical axis VA passing through the geometrical center of the electrostatic chuck 220. The total number of conductive inner edge ring segments 242 can be N, which is an integer greater than 2, i.e., an integer such as 3, 4, 5, 6, 7, 8, etc., such as 3 to 60. In this case, each of the conductive inner edge ring segments 242 can azimuthally extend around the vertical axis VA passing through the geometrical center of the electrostatic chuck 220 by an azimuthal angle range of 2π/N.

Each of the conductive inner edge ring segments can be numerically numbered employing integers beginning with 1. Thus, if N conductive inner edge ring segments are provided, the N conductive inner edge ring segments can include a first conductive inner edge ring segment 242_1, a second conductive inner edge ring segment 242_2, a third conductive inner edge ring segment 242_3, and so on up to the N-th conductive inner edge ring segment 242_N. An i-th conductive inner edge ring segment 242 can be located between an (i−1)-th conductive inner edge ring segment 144_(i−1) and an (i+1)-th conductive inner edge ring segment 144_(i+1) for all i other than 1 and N. In one embodiment, each of the plurality of conductive inner edge ring segments 242 can have an azimuthal extent in a range from π/30 radian to 2π/3 radian. In one embodiment, the N conductive inner edge ring segments 242 can be arranged with an N-fold rotational symmetry around the vertical axis VA passing through the geometrical center of the electrostatic chuck 220 in a plan view, i.e., a view along a downward vertical direction. In one embodiment, each of the N conductive inner edge ring segments 242 can be electrically connected to a respective one of the N conductive outer edge ring segments 144.

In the second embodiment, each of the combination ring segments (242, 144) containing one conductive inner edge ring segment 242 which is electrically connected to a respective one conductive outer edge ring segment 144 is electrically connected to a different auxiliary RF power source 190. There may be N auxiliary RF power sources 190 (i.e., 190_1, 190_2, 190_3, . . . 190_i, . . . 190_N), each electrically connected to one of the N combination ring segments (242, 144). Each of the auxiliary power sources may apply different RF bias voltage to different combination ring segment (242, 144). In the second embodiment of the present disclosure, each outer edge ring segment 144 may be raised and lowered independently from the other outer edge ring segments 144.

FIG. 1E illustrates an edge ring of the third embodiment. In a third embodiment each outer edge ring segment may not be raised and lowered independently from the other outer edge ring segments. In the third embodiment, each combination ring segment 342 may comprise a unitary structure in which the outer edge ring segment and the respective inner edge ring segment are formed from the same piece of metal or metal alloy. Each combination ring segment 342_i is electrically connected to a different auxiliary RF power source 190_i which can apply a different RF bias voltage to each combination ring segment 342_i, as shown in FIG. 1E. There may be N auxiliary RF power sources 190 (i.e., 190_1, 190_2, 190_3, . . . 190_i, . . . 190_N), each electrically connected to one of the N combination ring segments 342 (i.e., 342_1, 342_2, 342_3, . . . 342_i, . . . 342_N).

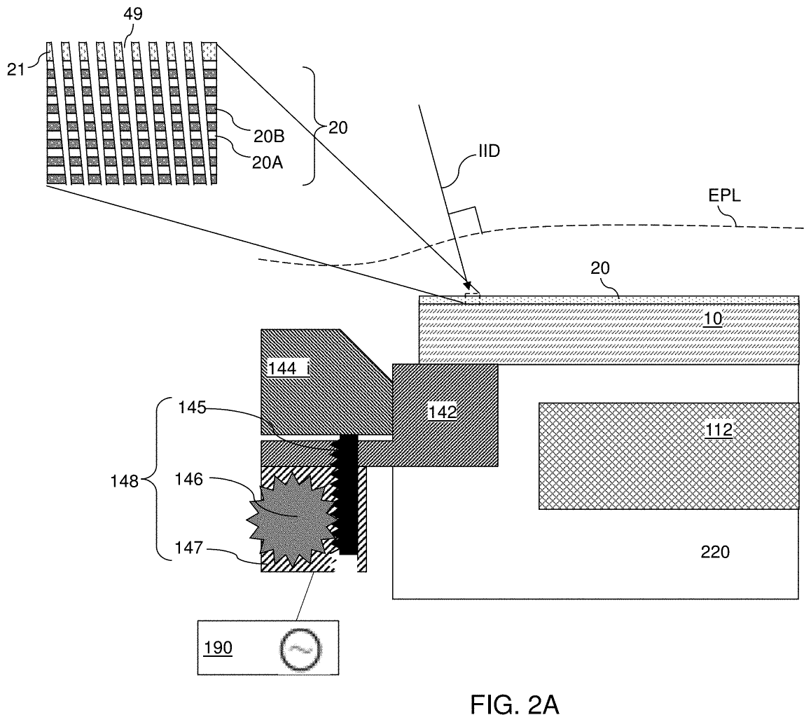

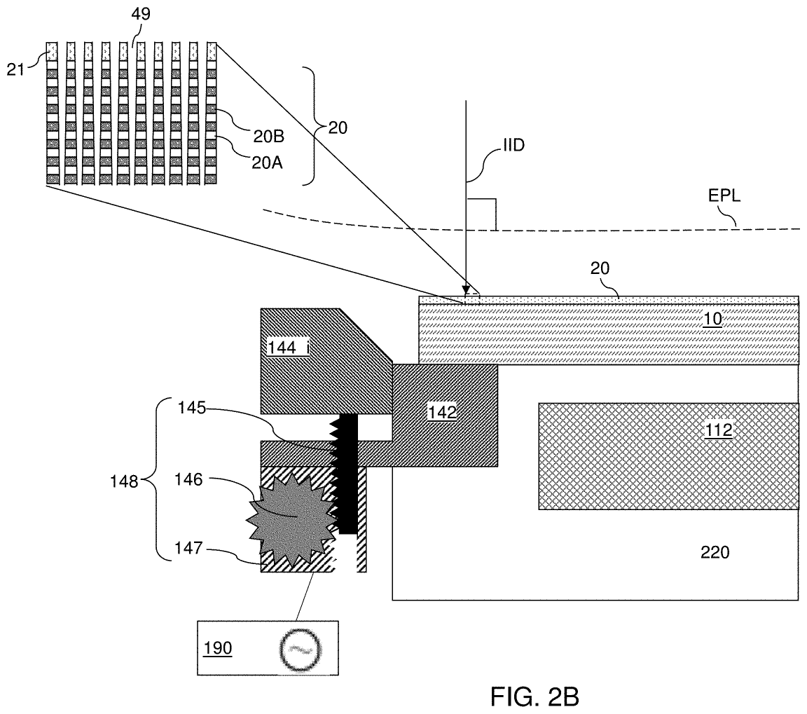

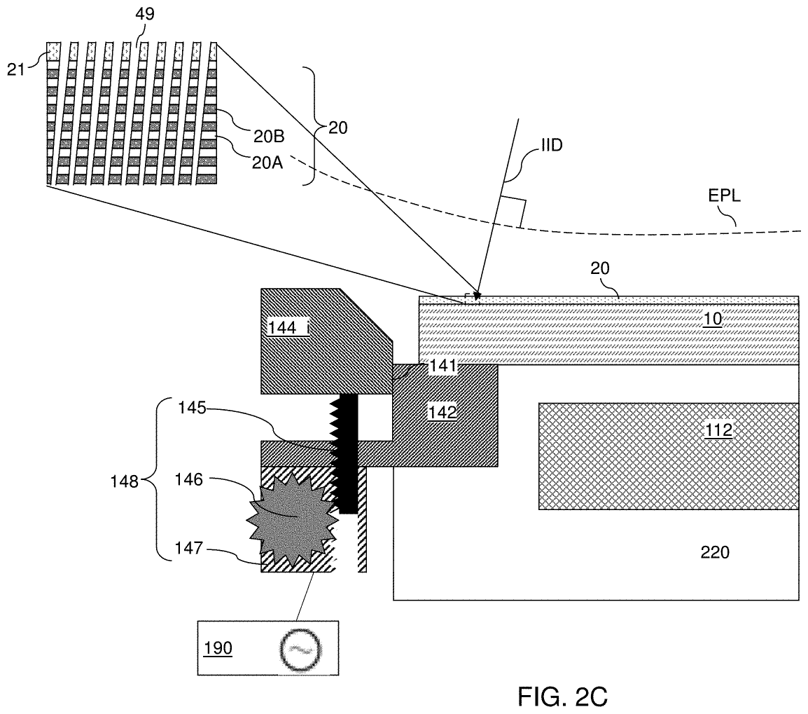

Referring to FIGS. 2A-2C, examples of etch direction adjustment at the periphery of a substrate 10 employing vertical movement of a conductive outer edge ring segment 144 of a first embodiment are illustrated.

FIG. 2A illustrates an example of an asymmetric tilt of the edge ring. The position of one conductive outer edge ring segment 144_i is too low compared to other outer edge ring segments 144 shown in FIG. 1B at a given azimuthal angle around the vertical axis VA passing through the geometrical center of the electrostatic chuck 220. In this case, the equipotential line EPL slopes downward with an increase in the radial distance from the vertical axis VA passing through the geometrical center of the electrostatic chuck 220, and the ion impingement direction IID is tilted toward the center of the substrate 10 near the outer edge ring segment 144_i. If the substrate 10 includes at least one material layer 20 (such as an alternating stack of first material layers 20A and second material layers 20B) with a patterned etch mask layer 21 thereupon, the etch direction of trenches 49 formed through the at least one material layer 20 is parallel to the ion impingement direction IID. In other words, the trenches 49 can be formed with a non-zero tilt angle with respect to the vertical direction.

In this case, the tilt in the trenches 49 through the at least one material layer 20 can be reduced or eliminated by raising the conductive outer edge ring segment 144_i, for example, by actuating the corresponding actuator 147, without necessarily raising or lowering the other outer edge ring segments 144 to remedy the asymmetric tilt of the edge ring. FIG. 2B illustrates a configuration that can be obtained by adjusting the height of the conductive outer edge ring segment 144 to an optimal level. In this case, the equipotential line EPL is flat around the edge of the substrate 10 irrespective of the radial distance from the vertical axis VA passing through the geometrical center of the electrostatic chuck 220. The ion impingement direction IID is vertical near the outer edge ring segment 144_i, and therefore, the etch direction of trenches 49 formed through the at least one material layer 20 is vertical. In other words, the trenches 49 can be formed with a vertical profile.

Referring to FIG. 2C, a configuration is illustrated in which the position of one of the conductive outer edge ring segments 144_i is too high compared to the other outer edge ring segments 144. In this case, the equipotential line EPL slopes upward with an increase in the radial distance from the vertical axis VA passing through the geometrical center of the electrostatic chuck 220, and the ion impingement direction IID is tilted outward, i.e., away from the center of the substrate 10 near the outer edge ring segment 144_i. The trenches 49 can be formed with an outward non-zero tilt angle with respect to the vertical direction. The tilt in the trenches 49 through the at least one material layer 20 can be reduced or eliminated by lowering the conductive outer edge ring segment 144, for example, by actuating the corresponding actuator 147, as shown in FIG. 2B.

Referring to the second embodiment shown in FIGS. 1C and 1D, if the position of one of the conductive outer edge ring segments 144_i is lower than that of the other outer edge ring segments 144, then a higher auxiliary RF bias voltage is applied to the combination edge ring segment (242, 144_i) containing this outer edge ring segment 144_i by its respective RF power source 190_i than the auxiliary RF bias voltages applied to other combination edge ring segments (242, 144) containing the outer edge ring segments 144 by their respective RF power sources 190 in addition to raising the outer edge ring segment 144_i. In contrast, if the position of one of the conductive outer edge ring segments 144_i is higher than that of the other outer edge ring segments 144, then a lower auxiliary RF bias voltage is applied to the combination edge ring segment (242, 144_i) containing this outer edge ring segment 144_i by its respective RF power source 190_i than the auxiliary RF bias voltages applied to other combination edge ring segments (242, 144) containing other outer edge ring segments 144 by their respective RF power sources 190 in addition to lowering the outer edge ring segment 144_i. These combined actions cause the equipotential line EPL to become around the edge of the substrate 10 irrespective of the radial distance from the vertical axis VA passing through the geometrical center of the electrostatic chuck 220.

Referring to the third embodiment shown in FIG. 1E, if the position of one of the combination ring segment 342_i is lower than that of the other combination ring segments 342, then a higher auxiliary RF bias voltage is applied to this combination edge ring segment 342_i by its respective RF power source 190_i than the auxiliary RF bias voltages applied to other combination edge ring segments 342 by their respective RF power sources 190. In contrast, if the position of one of the combination ring segments 342_i is higher than that of the other combination ring segments 342, then a lower auxiliary RF bias voltage is applied to this combination edge ring segment 342_i by its respective RF power source 190_i than the auxiliary RF bias voltages applied to other combination edge ring segments 342 by their respective RF power sources 190. These combined actions cause the equipotential line EPL to become around the edge of the substrate 10 irrespective of the radial distance from the vertical axis VA passing through the geometrical center of the electrostatic chuck 220, without raising or lowering any edge ring segments.

Referring to all drawings and according to various embodiments of the present disclosure, a method of operating an anisotropic etch apparatus 100 of the present disclosure is provided. A substrate 10 can be loaded on a top surface of the electrostatic chuck 220, and portions of the substrate 10 can be anisotropically etched employing a reactive ion etch process.

In one embodiment, the method further comprises vertically moving a first one of the conductive outer edge ring segments 144 without moving a second one of the conductive outer edge ring segments 144. In one embodiment, the method further comprises applying a first auxiliary RF bias voltage to the first one of the conductive outer edge ring segments and applying a second auxiliary RF bias voltage different from the first auxiliary bias voltage to the second one of the conductive outer edge ring segments.

In one embodiment, a patterned etch mask layer 21 can be formed over a front surface of the substrate 10 prior to loading the substrate 10 on the top surface of the electrostatic chuck 220. The portions of the substrate 10 (e.g., layers located over the substrate) that are anisotropically etched comprise portions of the substrate 10 that are not masked by the patterned etch mask layer 21.

Adjustment of the ion impingement direction IID may be based on measurement of etch directions on a previously processed substrate 10. For example, the substrate 10 can be unloaded after the reactive ion etch process, and the tilt angle of etch patterns can be measured at a peripheral region of the substrate 10. The height of at least one of the plurality of conductive outer edge ring segments 144 located at a position corresponding to a non-zero tilt angle in the etch patterns can be subsequently adjusted and/or an auxiliary RF bias voltage may be adjusted so that the next substrate can be processed with reduced tilt angles throughout all azimuthal angle ranges.

In one embodiment, the anisotropic etch apparatus 100 can comprise a plurality of height adjustment assemblies 148 configured to independently elevate or lower a respective one of the plurality of conductive outer edge ring segments 144. Each of the plurality height adjustment assemblies 148 can comprise an actuator 147 located within the vacuum enclosure 110 or outside the vacuum enclosure 110 and configured to actuate vertical movement of a conductive outer edge ring segment 144. The height of at least one of the plurality of conductive outer edge ring segments 144 can be adjusted by actuating at least one actuator 147 connected to at least one of the plurality of conductive outer edge ring segments 144.

The various embodiments of the present disclosure can be employed to reduce or eliminate asymmetric tilt of the edge ring to provide a substantially vertical ion impingement directions IID across the entire periphery of a substrate 10 irrespective of any disturbances to the equipotential line EPL due to any nonuniformity in the surface conditions and/or geometrical conditions in the anisotropic etch apparatus 100. Trenches and via openings through material layers on a substrate can be formed with a more uniform vertical profile employing the anisotropic etch apparatus 100 of the present disclosure.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. An anisotropic etch apparatus comprising:
an electrostatic chuck located in a vacuum enclosure and including a lower electrode therein;
a plurality of conductive outer edge ring segments surrounding the electrostatic chuck and configured for independent vertical movement relative to the electrostatic chuck;
an upper electrode overlying the lower electrode and located in the vacuum enclosure; and
a main radio frequency (RF) power source configured to provide radio frequency bias voltage between the lower electrode and the upper electrode.

2. The anisotropic etch apparatus of claim 1, further comprising a plurality of height adjustment assemblies configured to independently elevate or lower a respective one of the plurality of conductive outer edge ring segments.

3. The anisotropic etch apparatus of claim 2, wherein:
each of the plurality height adjustment assemblies comprises an actuator located within the vacuum enclosure or outside the vacuum enclosure and configured to actuate vertical movement of a respective height adjustment assembly; and
the anisotropic etch apparatus further comprises a differential height controller configured to independently actuate each of the actuators for the plurality height adjustment assemblies.

4. The anisotropic etch apparatus of claim 2, wherein each of the plurality height adjustment assemblies is configured to mechanically actuate a respective one of the plurality of conductive outer edge ring segments upon application of physical force thereto.

5. The anisotropic etch apparatus of claim 2, further comprising an annular conductive edge ring that laterally surrounds the electrostatic chuck.

6. The anisotropic etch apparatus of claim 5, wherein:
the annular conductive edge ring comprises a laterally-protruding flange portion including holes; and
each height adjustment assembly comprises a component that vertically extends through a respective hole in the laterally-protruding flange portion of the annular conductive edge ring.

7. The anisotropic etch apparatus of claim 5, wherein:
each of the plurality of conductive outer edge ring segments comprises a respective inner sidewall that contacts a portion of a cylindrical sidewall of the annular conductive edge ring;
each inner sidewall of the plurality of conductive outer edge ring segments is vertical and has a concave profile in a horizontal cross-sectional view;
each of the plurality of conductive outer edge ring segments has an azimuthal extent in a range from π/30 radian to 2π/3 radian;
the plurality of conductive outer edge ring segments comprises N conductive outer edge ring segments, and wherein N is in a range from 3 to 60; and
the N conductive outer edge ring segments are arranged with an N-fold rotational symmetry around a vertical axis passing through a geometrical center of the electrostatic chuck in a plan view.

8. The anisotropic etch apparatus of claim 5, further comprising at least one auxiliary RF power source configured to provide an auxiliary RF bias voltage to the annular conductive edge ring.

9. The anisotropic etch apparatus of claim 8, wherein:
the annular conductive edge ring comprises a plurality of electrically isolated conductive inner edge ring segments which are electrically connected to a respective one of the conductive outer edge ring segments; and
the at least one auxiliary RF power source comprises a plurality of auxiliary RF power sources, each of which is configured to independently provide a different auxiliary RF bias voltage to one of the conductive outer edge ring segments.

10. The anisotropic etch apparatus of claim 1, wherein each of the plurality of conductive outer edge ring segments comprises a tapered top surface having a height that increases with a radial distance from a vertical axis passing through a geometrical center of the electrostatic chuck.

11. The anisotropic etch apparatus of claim 1, wherein:
each of the plurality of conductive outer edge ring segments is configured to vertically move by at least 1 mm;
a volume between the electrostatic chuck and the upper electrode comprises a plasma zone; and
the plurality of conductive outer edge ring segments is arranged along a periphery of the plasma zone.

12. A method of operating the anisotropic etch apparatus of claim 1, comprising:
loading a substrate on a top surface of the electrostatic chuck; and
anisotropically etching portions of the substrate employing a reactive ion etch process.

13. The method of claim 12, further comprising vertically moving a first one of the conductive outer edge ring segments without moving a second one of the conductive outer edge ring segments.

14. The method of claim 13, further comprising applying a first auxiliary RF bias voltage to the first one of the conductive outer edge ring segments and applying a second auxiliary RF bias voltage different from the first auxiliary bias voltage to the second one of the conductive outer edge ring segments.

15. An anisotropic etch apparatus comprising:
an electrostatic chuck located in a vacuum enclosure and including a lower electrode therein;
an upper electrode overlying the lower electrode and located in the vacuum enclosure;
a main radio frequency (RF) power source configured to provide radio frequency bias voltage between the lower electrode and the upper electrode;
a plurality of electrically isolated, conductive edge ring segments surrounding the electrostatic chuck; and
a plurality of auxiliary RF power sources, each of which is configured to independently provide a different auxiliary RF bias voltage to one of the conductive edge ring segments.

16. The anisotropic etch apparatus of claim 15, wherein each of the conductive edge ring segments comprises a unitary structure.

17. The anisotropic etch apparatus of claim 15, wherein each of the conductive edge ring segments comprises a conductive inner edge ring segment and a conductive outer edge ring segment which is configured to be moved vertically respective to the conductive inner edge ring segment.

18. A method of operating the anisotropic etch apparatus of claim 15, comprising:
loading a substrate on a top surface of the electrostatic chuck; and
anisotropically etching portions of the substrate employing a reactive ion etch process.

19. The method of claim 18, further comprising applying a first auxiliary RF bias voltage to the first one of the conductive edge ring segments and applying a second auxiliary RF bias voltage different from the first auxiliary bias voltage to the second one of the conductive edge ring segments.

20. The method of claim 19, further comprising vertically moving one of the conductive edge ring segments without moving a second one of the conductive edge ring segments.
